(19) United States
(12) Patent Application Publication
(10) Pub. No.: US 2008/0160713 A1
(43) Pub. Date: Jul. 3, 2008

(54) SIMULTANEOUSLY FORMING HIGH-SPEED AND LOW-POWER MEMORY DEVICES ON A SINGLE SUBSTRATE

(76) Inventors: Kangguo Cheng, Beacon, NY (US); Ramachandra Divakaruni, Ossining, NY (US); Carl J. Radens, LaGrangeville, NY (US)

Correspondence Address: FREDERICK W. GIBB, III;Gibb & Rahman, LLC, 2568-A RIVA ROAD, SUITE 304, ANNAPOLIS, MD, 21401, US

(21) Appl. No.: 11/617,960

(22) Filed: Dec. 29, 2006

(51) Int. Cl. H01L 21/28

(52) U.S. Cl. 438/386; 257/E21.008

(57) ABSTRACT

A method patterns a trench mask over both SOI regions and bulk silicon regions of a single substrate. Next, the SOI regions and the bulk silicon regions are simultaneously etched through the trench mask to form trenches in the SOI regions and the bulk silicon regions. In such processing the buried insulating layer in SOI regions causes trenches within the SOI regions to be less deep (more shallow) than trenches in the bulk silicon regions (which are deeper or less shallow). After the trenches are formed, the method completes the process by forming capacitors in the trenches. More specifically, the method simultaneously lines all of the trenches with an insulator and simultaneously fills all of the trenches with a conductor to form capacitors in the trenches. The capacitors within the SOI regions have a lower capacitance that the capacitors within the SOI regions.

### BACKGROUND

1. Field of the Invention

The embodiments of the invention generally relate to semiconductor chip manufacturing, and, more particularly, to simultaneous manufacturing of different capacitors on a semiconductor wafer.

2. Description of the Related Art

Emerging system-on-chip (SoC) technology calls for integration of various memories on the same chip. For example, high-speed embedded dynamic random access memory (DRAM) devices are desired for level-2 (L2) caches of a microprocessor to match or closely match the performance of SRAM with increased density. A relative low capacitance is desired for high-speed memories as the time for charging the capacitor is relatively short so that the data can be stored and read quickly. On the other hand, low-power embedded DRAM is desired for level-3 (L3) caches which require a relatively high capacitance for a relative long retention time so that data can be stored for a long time without consuming power for refreshing. In another application, decoupling capacitors with capacitances as high as possible are desired.

The performance and power of a SoC chip can be optimized by forming different capacitors on the same chip. For example, U.S. Pat. No. 6,566,191 entitled “Forming electronic structures having dual dielectric thicknesses and the structure so formed” (incorporated herein by reference) teaches a method for forming two trench capacitors with different capacitances with different dielectric thicknesses. U.S. Pat. No. 7,084,449 entitled “Microelectronic element having trench capacitors with different capacitance values” (incorporated herein by reference) teaches a method for forming two trench capacitors with different capacitances by recessing the polysilicon deeper in one trench than the other. However, these systems have at least one of following the disadvantages: requirement of an extra mask level, requirement of extra process steps, difficulty in process control, and defect issues.

Therefore, it is desired to have a simple process for forming different capacitors with different capacitances on the same chip without adding process complexity or increasing process cost.

### SUMMARY

In view of the foregoing, embodiments herein provide a method of simultaneously manufacturing different trench capacitors within a single semiconductor wafer that has bulk semiconductor regions and semiconductor-on-insulator (SOI) regions. A trench mask is formed over both the SOI regions and the bulk semiconductor regions. Next, the SOI regions and the bulk semiconductor regions are simultaneously etched through the trench mask to form trenches in the SOI regions and the bulk semiconductor regions. In such processing the buried insulator layer in the SOI regions causes trenches within the SOI regions to be less deep (more shallow or shallower) than trenches in the bulk semiconductor regions (which are deeper or less shallow).

After the trenches are formed, the method completes the process by forming capacitors in the trenches. More specifically, the method simultaneously lines all of the trenches with an insulator and simultaneously fills all of the trenches with a conductor to form capacitors in the trenches. The capacitors within the SOI regions have a lower capacitance than the capacitors within the bulk semiconductor regions.

These and other aspects of the embodiments of the invention will be better appreciated and understood when considered in conjunction with the following description and the accompanying drawings. It should be understood, however, that the following descriptions, while indicating preferred embodiments of the invention and numerous specific details thereof, are given by way of illustration and not of limitation. Many changes and modifications may be made within the scope of the embodiments of the invention without departing from the spirit thereof, and the embodiments of the invention include all such modifications.

### BRIEF DESCRIPTION OF THE DRAWINGS

The embodiments of the invention will be better understood from the following detailed description with reference to the drawings, in which:

FIG. 1 is a cross-sectional schematic diagram of a wafer structure;

FIG. 2 is a cross-sectional schematic diagram of a wafer structure having trenches;

FIG. 3 is a cross-sectional schematic diagram of a wafer structure having partial trenches;

FIG. 4 is a cross-sectional schematic diagram of a wafer structure having partial trenches;

FIG. 5 is a cross-sectional schematic diagram of a wafer structure having capacitors and transistors; and

FIG. 6 is a cross-sectional schematic diagram of a wafer structure having capacitors and transistors.

### DETAILED DESCRIPTION OF PREFERRED EMBODIMENTS

The embodiments of the invention and the various features and advantageous details thereof are explained more fully with reference to the non-limiting embodiments that are illustrated in the accompanying drawings and detailed in the following description. It should be noted that the features illustrated in the drawings are not necessarily drawn to scale. Descriptions of well-known components and processing techniques are omitted so as not to unnecessarily obscure the embodiments of the invention. The examples used herein are intended merely to facilitate an understanding of ways in which the embodiments of the invention may be practiced and to further enable those of skill in the art to practice the embodiments of the invention. Accordingly, the examples should not be construed as limiting the scope of the embodiments of the invention.

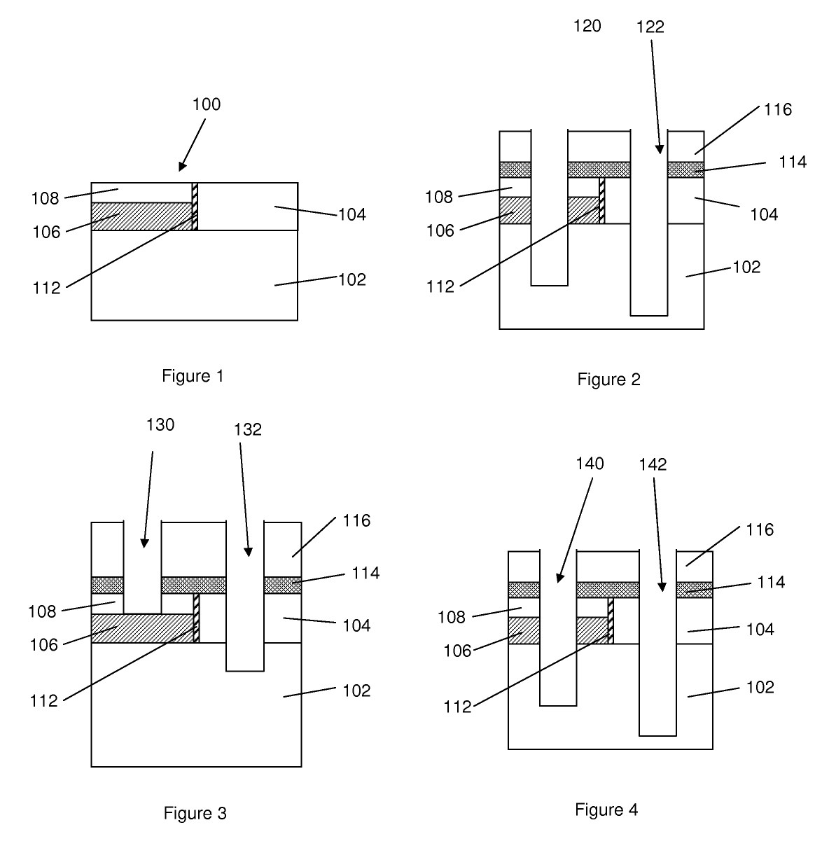

As mentioned above, embodiments herein provide a method of simultaneously manufacturing different trench capacitors within a single semiconductor substrate 100 as shown in FIG. 1. The semiconductor substrate 100 comprises bulk semiconductor regions 104 and semiconductor-on-insulator (SOI) regions 106/108. Each SOI region comprises a semiconductor region 108 on top of a buried insulator region 106. Both bulk regions 104 and SOI regions 106/108 are formed on a base region 102. The substrate 100 may further comprise an optional spacer 112 which may comprise an oxide or a nitride and separates the bulk semiconductor regions 104 and semiconductor-on-insulator (SOI) regions 106/108. Various methods, such as wafer bonding, epitaxial growth, or combination of these techniques, can be used for forming the substrate 100. For details on the formation of the substrate 100, see U.S. Pat. No. 6,107,125, U.S. Pat. No. 6,555,891, U.S. Pat. No. 6,635,543, and U.S. Patent Publication 2004/0256700, which are incorporated herein by reference.

In one embodiment, the semiconductor regions 104 and 108 comprise silicon. Besides silicon, other semiconductor materials can also be used as the substrate, such as germanium, silicon germanium, silicon carbide, and those consisting essentially of one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions, each greater than or equal to zero and X1+X2+X3+Y1+Y2+Y3+Y4=1 (1 being the total relative mole quantity). Other suitable materials include II-VI compound semiconductors having a composition Zn_{A1}Cd_{A2}Se_{B1}Te_{B2}, where A1, A2, B1, and B2 are relative proportions each greater than or equal to zero and A1+A2+B1+B2=1 (1 being a total mole quantity). A portion or entire semiconductor regions 104 and/or 108 may be amorphous, polycrystalline, or single-crystalline. A portion or entire semiconductor regions 104 and/or 108 may be strained. The semiconductor regions 104 and the semiconductor regions 108 may comprise the same or different materials. The semiconductor regions 104 and the semiconductor regions 108 may have the same or different crystallographic orientations.

The base region 102 may comprise the same material as the semiconductor regions 108. Alternatively, the base region 102 comprises a material different from the semiconductor regions 108.

Thus, the process starts with such a semiconductor substrate 100 having at least one SOI area 106/108 and at least one bulk area 104. In one embodiment, the substrate 100 is a hybrid orientation substrate, i.e., the semiconductor regions 104 and the semiconductor regions 108 have the different crystallographic orientations. Methods for forming such a hybrid orientation substrate and hybrid orientation structures can be found in references, for example, U.S. patents and patent applications U.S. Pat. No. 6,815,278, U.S. Patent Publications 2004/0256700A1, and 2005/0236687A1, (incorporated herein by reference) and articles “In-Plane Mobility Anisotropy and Universality Under Uni-axial Strains in n- and p-MOS Inversion Layers on (100), (110), and (111) Si”, H. Irie, et al., IEDM, 2004; and “High Performance CMOS Fabricated on Hybrid Substrate With Different Crystal Orientations”, M. Yang, et al., IEDM, 2003. Since such technologies are well know, the details of the same are not discussed in detail herein.

Referring to FIG. 2, the method can pattern a trench mask layer 116 over both the SOI regions 106/108 and the bulk silicon regions 104. Next, the SOI regions 106/108 and the bulk silicon regions 104 are simultaneously etched through the trench mask 116 to form trenches 120, 122 in the SOI regions 106/108 and the bulk silicon regions 104. In such processing the buried insulating layer 106 (e.g., oxide) causes trenches 120 within the SOI regions 106/108 to be less deep (more shallow or shallower) than trenches 122 in the bulk silicon regions 104 (which are deeper or less shallow).

More specifically, a pad layer 114 (e.g., a pad nitride layer with an optional underlying pad oxide layer) and a hardmask 116 (HM) layer (e.g., oxide) are deposited. Standard patterning (e.g., lithography) and etching (e.g., reactive ion etch (RIE)) are performed to form the trenches 120, 122 in both SOI area 106/108 and bulk area 104. The RIE process is performed to transfer the trench patterns from the mask 116 into the base region 102. Due to the resistance of the buried oxide (BOX) layer 106 in the silicon RIE process, the trench 120 formed in the SOI area 106/108 is shallower than the trench 122 formed in the bulk area 104.

FIGS. 3 and 4 shows the intermediate structures before the structure shown in FIG. 2. Specifically, after the pad layer 114 and the hardmask layer 116 are deposited and patterned, a multi-etch process that includes multiple etching steps is performed. In such a multi-etch process, a first etching process removes the semiconductor region 108, the bulk semiconductor region 104 and part of the base region 102 through the trench mask 116, as shown in FIG. 3. For example, when the semiconductor regions 104, 108 and the base region 102 comprise silicon and the buried insulating layer 106 comprises silicon oxide, the first etching can comprise a silicon etch selective to oxide, resulting in deepening the trench 132 in the bulk area 104 only and not the trench 130 in the SOI region 106/108 because the buried oxide (BOX) 106 acts as a mask to prevent deepening the trench in SOI area 106/108.

A second etching process (which may (or may not) use different etchants or different powers/voltage than the first etching process) removes the oxide layer 106 through the trench mask 116 (trench 140) and more of the base region 102 (trench 142), as shown in FIG. 4. For example, the second etching can comprise a non-selective etch in which both the buried oxide 106 and the silicon 102 are etched. Alternatively, an oxide etch selective to silicon can be performed to open the buried oxide 106 in SOI area 106/108 without deepening the trench 142 in the bulk area 104.

A third etching process (which, again, may or may not use different etchants and powers/voltages than the first two etching processes) removes the bulk silicon 102 through the trench mask 116, as shown in FIG. 2. This third step comprises a silicon etch which deepens both trenches 120, 122 simultaneously, resulting in two trenches 120, 122 in FIG. 2 that have different depths.

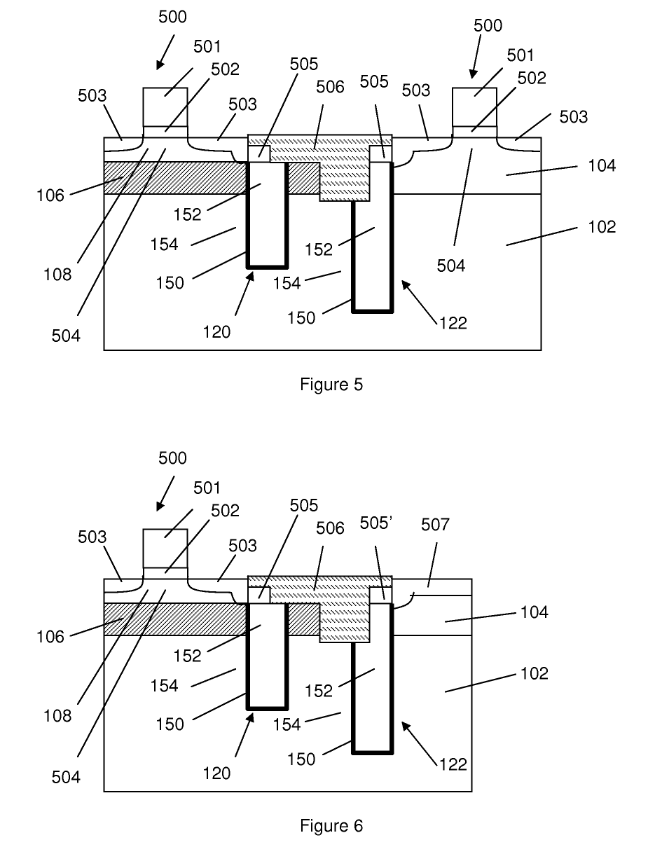

After forming the trenches 120, 122, the method completes the capacitors by forming electrodes in the trenches 120, 122, as shown in FIG. 5. More specifically, the method simultaneously lines all of the trenches 120, 122 with an insulator 150 and simultaneously fills all of the trenches 120, 122 with a conductor (electrode) 152 to form capacitors in the trenches 120, 122. The capacitors 120 within the SOI regions 106/108 have a lower capacitance that the capacitors 120 within the bulk regions 104 because of their smaller size (depth).

A memory cell having the shallower trench capacitor(s) 120 can be used for high-speed applications as less time is required for charge storing or removing. A memory cell having the deeper trench capacitor(s) 122 can be used for low-power application as a charge can be stored to it for a longer time without refreshing.

Referring to FIG. 5, standard trench processes are performed to form trench capacitors which comprise an electrode 154 in the substrate 102 and another electrode 152 inside the trench. These two electrodes are separated by the node dielectric 150 (e.g., oxide, nitride, oxynitride, high-k materials, etc.). The electrode 154 in the substrate 102 may be doped to form a buried plate (not shown). The depth difference between these two trenches 120, 122 results in two capacitors with different capacitances. When the capacitors are electrically connected to transistors 500, as shown in FIG. 5, an integrated circuit with two memory cells is formed. One transistor is formed in the SOI region 106/108 and the other transistor is formed in the bulk region 104. As is well known in the art, each transistors 500 may include a gate 501, a gate dielectrics 501, two source/drain regions 503 that are separated by a channel region 504, etc. The transistors can be separated by a shallow trench isolation (STI) region 506. The transistor is electrically connected to the electrode 152 of the capacitor 120 or 122 through a strap 505. Processes for forming the these structures are well known in the art and are not discussed herein in detail.

FIG. 6 shows another embodiment in which the shallower trench capacitor 120 is electrically connected to a transistor to form a memory cell while the deeper trench capacitor 122 stands alone as a decoupling capacitor. Specifically, a transistor 500 is formed in the SOI region 106/108. As is well known in the art, the transistors 500 can include a gate 501, a gate dielectrics 501, two source/drain regions 503 that are separated by a channel region 504, etc. The transistors can be separated by a shallow trench isolation (STI) region 506. The transistor is electrically connected to the electrode 152 of the capacitor 120 through a strap 505. The trench capacitor 122 stands alone as a decoupling capacitor. An external contact region 507 can be formed and it is electrically connected to the electrode 152 of the trench capacitor 122 through the buried strap 505′.

Thus, as shown above, the invention provides a method for forming various depth capacitors on the same hybrid oriented substrate. This results in an integrated circuit with both high-speed memory and low-power memory on the same chip. This also results in an integrated circuit with high-speed memory and high-capacitance decoupling capacitors on the same chip. With the invention, different size trench capacitors are formed on the same chip without adding any extra complexity or cost because a unified etch process can be used to etch all trenches 120, 122.

The foregoing description of the specific embodiments will so fully reveal the general nature of the invention that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments of the invention have been described in terms of preferred embodiments, those skilled in the art will recognize that the embodiments of the invention can be practiced with modification within the spirit and scope of the appended claims.

What is claimed is:

1. A method of simultaneously manufacturing different trench capacitors within a single semiconductor substrate comprising:
providing said semiconductor substrate having a bulk semiconductor region and a semiconductor-on-insulator (SOI) region;
patterning a trench mask over said SOI region and said bulk semiconductor region; and
simultaneously etching said SOI region and said bulk semiconductor region through said trench mask to form a first trench in said SOI region and a second trench in said bulk semiconductor region,
wherein the depth of said first trench within said SOI region is less than the depth of said second trench in said bulk semiconductor region.

2. The method according to claim 1, further comprising:
simultaneously lining all of said trenches with an insulator; and
simultaneously filling all of said trenches with a conductor to form capacitors in said trenches.

3. The method according to claim 2, wherein said capacitors within said SOI region have a lower capacitance that said capacitors within said bulk semiconductor region.

4. A method of simultaneously manufacturing different trench capacitors within a single semiconductor substrate comprising:
providing said semiconductor substrate having a bulk semiconductor region and a semiconductor-on-insulator (SOI) region wherein said SOI region comprises a semiconductor layer on a buried insulating layer;
patterning a trench mask over said SOI region and said bulk semiconductor region; and
simultaneously etching said SOI region and said bulk semiconductor region through said trench mask to form a first trench in said SOI region and a second trench in said bulk silicon region,
wherein the depth of said first trench within said SOI region is less than the depth of said second trench in said bulk semiconductor region, and
wherein said etching comprises:
a first etching process that simultaneously removes a first part of said bulk silicon and said semiconductor layer within said SOI region through said trench mask;
a second etching process that removes said buried insulating layer through said trench mask; and
a third etching process that removes a second part of said bulk silicon through said trench mask.

5. The method according to claim 4, further comprising:
simultaneously lining all of said trenches with an insulator; and
simultaneously filling all of said trenches with a conductor to form capacitors in said trenches.

6. The method according to claim 5, wherein said capacitor within said SOI region has a lower capacitance that said capacitor within said bulk semiconductor region.
